(19) United States
(12) Patent Application Publication
(10) Pub. No.: US 2026/0360677 A1
(43) Pub. Date: Nov. 12, 2026

(54) ION-DEPLETION MODE DEPOSITION PROCESSES

(71) Applicant: Applied Materials, Inc., Santa Clara, CA (US)

(72) Inventors: Junjie PAN, Santa Clara, CA (US); Yao WU, Sunnyvale, CA (US); Xiangjin XIE, Fremont, CA (US); Kevin KASHEFI, Dublin, CA (US)

(21) Appl. No.: 19/205,974

(22) Filed: May 12, 2025

(51) Int. Cl. H01J 37/34; C23C 14/35

(52) U.S. Cl. CPC H01J 37/3461; C23C 14/35; H01J 37/3405; H01J 2237/332

(57) ABSTRACT

Embodiments of the present disclosure include a method of depositing a material layer on a surface of a substrate, comprising: generating a plasma within a processing region of a processing chamber, wherein the processing region is disposed between a target and a substrate support, the plasma is generated by biasing the target at a first power level while the processing region is maintained at a first processing pressure, and the plasma comprises ionized atoms sputtered from the target; applying a first bias to a first electromagnet that is positioned to generate a magnetic field within the processing region, wherein applying the first bias to the first electromagnet causes a flux of the ionized atoms sputtered from the target to be directed away from a surface of the substrate support, and the first bias is applied to the first electromagnet while the processing region is at a pressure between the first processing pressure and a second processing pressure and the target is biased at a second power level; and adjusting the bias applied to the target to a third power level while a pressure within the processing region is less than or equal to the second processing pressure.

### BACKGROUND

### Field

Embodiments of the present disclosure generally relate to processes of depositing a layer on a substrate during a semiconductor device fabrication process, and more particularly, to apparatus and methods for depositing one or more film layers in features formed on a substrate.

### Description of the Related Art

The field of semiconductor device fabrication is constantly evolving, with new materials, processes, and equipment being developed to meet the growing demand for smaller, faster, and more complex devices. One of the key challenges in device fabrication is the need to deposit thin films of various materials with high quality, uniformity, and precision.

Physical vapor deposition (PVD) is a common technique used for depositing thin films of various metals and metal alloys. However, to reliably ignite a plasma at the start of a PVD deposition process within a PVD processing chamber a sputtering gas, such as argon (Ar), is provided to achieve a moderate pressure (e.g., >20 mTorr) within the PVD processing chamber. However, a deposition rate achieved on a substrate at the moderate ignition pressures and DC power levels applied to the PVD target to ignite and then sustain the plasma during the initial phases of a PVD deposition process is often too high for a deposition process that requires very thin films to be deposited within small structures formed on a substrate, such as 15 nanometer (nm) structures. The characteristics of the deposited PVD film, which is formed by the generation of metal ions and neutrals from the target, are uncontrollable during these early stages of the deposition process and often account for an undesirably large percentage of the thickness of the to be deposited PVD film layer.

Therefore, there is a need for an improved deposition apparatus and process that can provide a thin and high-quality film that has desirable deposited film characteristics (e.g., step-coverage, bottom coverage, uniformity, etc.) without compromising the performance and reliability of the formed device.

### SUMMARY

Embodiments of the present disclosure generally relate to physical vapor deposition (PVD) film formation on substrates in a device fabrication process, and more particularly, to apparatus and methods for depositing one or more film layers in features formed on a substrate.

Embodiments of the present disclosure include a method of depositing a material layer on a surface of a substrate, comprising: generating a plasma within a processing region of a processing chamber, wherein the processing region is disposed between a target and a substrate support, the plasma is generated by biasing the target at a first power level while the processing region is maintained at a first processing pressure, and the plasma comprises ionized atoms sputtered from the target; applying a first bias to a first electromagnet that is positioned to generate a magnetic field within the processing region, wherein applying the first bias to the first electromagnet causes a flux of the ionized atoms sputtered from the target to be directed away from a surface of the substrate support, and the first bias is applied to the first electromagnet while the processing region is at a pressure between the first processing pressure and a second processing pressure and the target is biased at a second power level; and adjusting the bias applied to the target to a third power level while a pressure within the processing region is less than or equal to the second processing pressure. The method can include applying the first bias to the first electromagnet to reduce the flux of the ionized atoms reaching the surface of a substrate by at least 10%, or at least 50%, or at least 90%, or at least 95%, or even at least 99%.

Embodiments of the present disclosure include a processing chamber, comprising: a target, a substrate support, one or more walls, wherein the target, the substrate support and the one or more walls define a processing region, a first electromagnet that is that is positioned to generate a magnetic field within the processing region, and a memory that includes computer implemented instructions stored therein. The computer implemented instructions when executed by a processor is configured to perform a method comprising: generating a plasma within the processing region by biasing the target at a first power level while the processing region is maintained at a first processing pressure, wherein the plasma comprises ionized atoms sputtered from the target; applying a first bias to the first electromagnet, wherein applying the first bias causes a flux of the ionized atoms sputtered from the target to be directed away from the substrate support, and the first bias is applied to the first electromagnet while the processing region is at a pressure between the first processing pressure and a second processing pressure and the target is biased at a second power level; and adjusting the bias applied to the target to a third power level while a pressure within the processing region is less than or equal to the second processing pressure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic top view of an exemplary processing system according to an embodiment.

FIG. 2 is a cross-sectional view of an exemplary processing chamber according to an embodiment.

FIG. 3 is a perspective view of a flux optimizer, according to an embodiment.

FIG. 4 includes a curve that illustrates a chamber processing pressure as a function time during physical vapor deposition (PVD) process, according to an embodiment.

FIG. 5 is a process flow diagram of a deposition method, according to an embodiment.

FIG. 6 is a schematic representation of metal ion flux trajectory within the processing chamber during one or more operations performed during a deposition method, according to an embodiment.

FIG. 7 are illustrative representations of magnetic field lines formed within a portion of a processing region during one or more operations performed during a deposition method, according to an embodiment.

FIGS. 8A-8C are illustrative representations of magnetic field lines formed within a portion of a processing region during one or more operations performed during a deposition method, according to an embodiment.

FIG. 9 are illustrative representations of magnetic field lines formed within a portion of a processing region during one or more operations performed during a deposition method, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

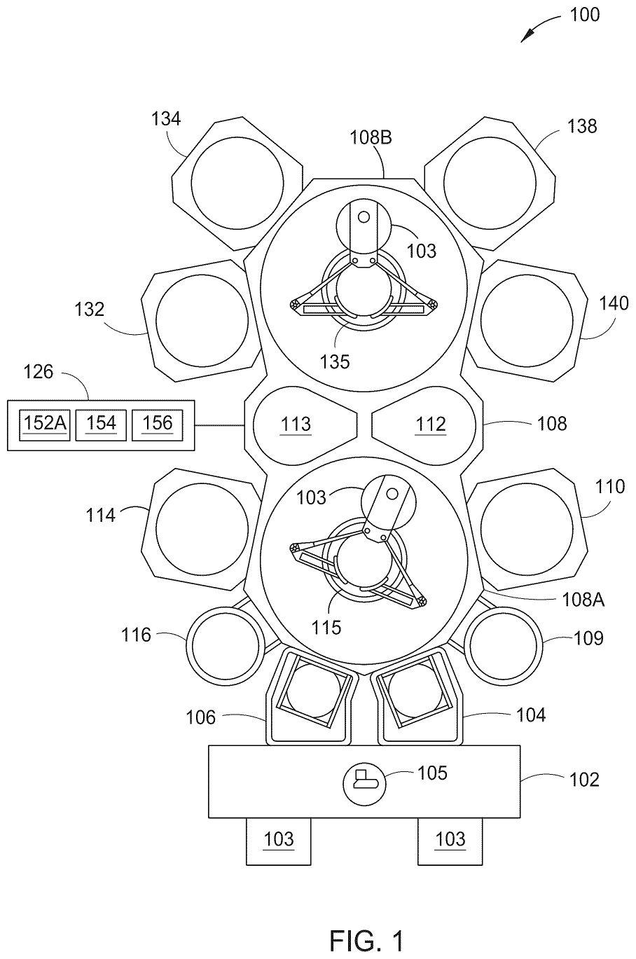

Embodiments of the present disclosure include a physical vapor deposition (PVD) chamber design that is adapted to deposit thin film layers on a surface of a substrate. In some embodiments, the PVD chamber includes deposition flux and field shaping components that are used to form thin films on a surface of a substrate. The deposition flux (e.g., number atoms (i.e., ionized atoms and neutral atoms) crossing a unit area per unit time) and field shaping components disclosed herein can be useful for depositing one or more layers of a material within a plurality of features formed on a surface of the substrate that have a narrow critical dimension (CD). Embodiments of the invention generally provide a processing chamber used to perform a PVD process useful for forming metal interconnects within the features formed on the surface of the substrate by controlling the ion flux (e.g., number of ions crossing a unit area per unit time) during one or more phases of a deposition process. The PVD processes described herein are often referred to as “sputtering” or a “sputtering process”, which is well known in the art as a process where energetic particles, typically ions, bombard a target material, causing the bombarded target material to eject atoms or molecules onto a substrate, to form a thin film. FIG. 1 is a schematic top view of a processing system 100 that includes a plurality of processing chambers, such as one or more of the processing chambers 110, 114, and 132-140, which are adapted to perform a PVD process.

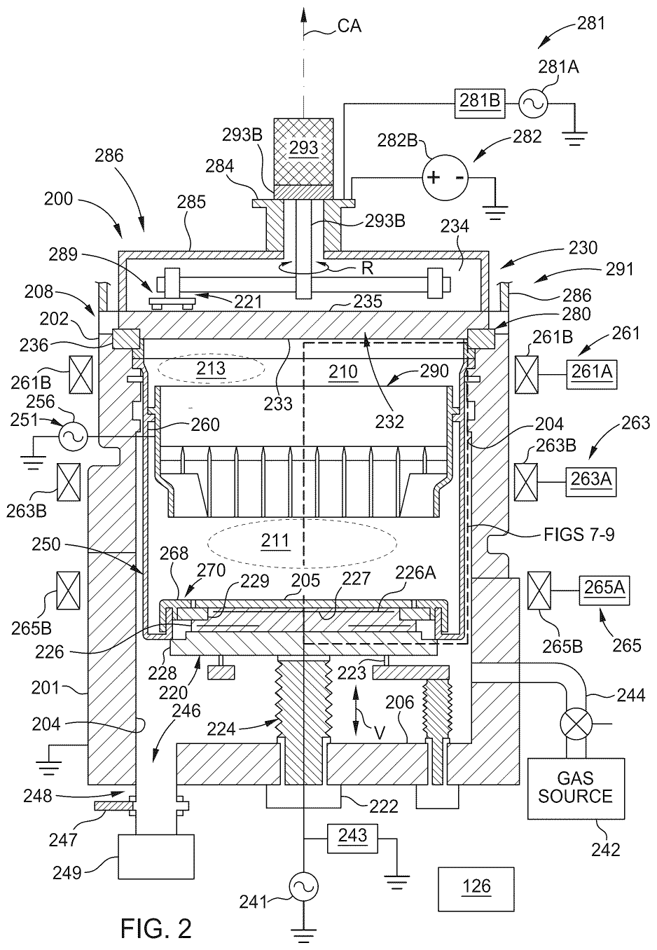

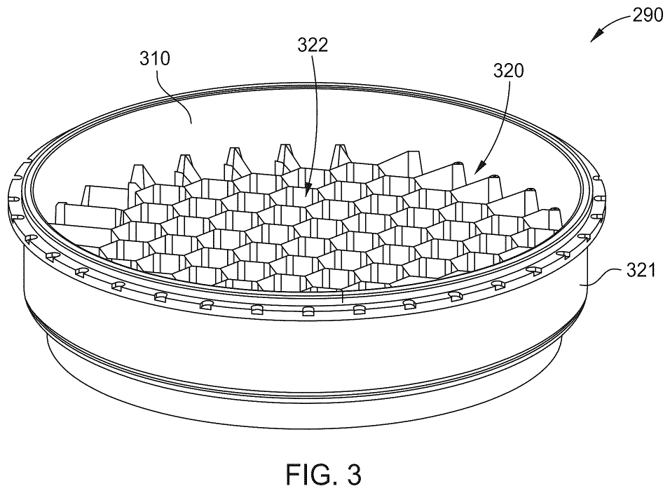

FIG. 2 is a cross-sectional view of a processing chamber 200 that can be positioned within one of the processing chambers 110, 114, and 132-140 of FIG. 1. FIG. 3 is a perspective view of a flux optimizer that can be used during a PVD process performed in one of the processing chambers of FIGS. 1-2. The processing chamber design disclosed herein may be especially useful for depositing films so that they have an improved deposition uniformity, feature side wall coverage and feature bottom coverage within small device features (e.g., vias, trenches, etc.) formed in a surface of a substrate. The processing chamber's design features may include a grounded or biasable flux optimizer (e.g., collimator), one or more side wall electromagnets, an improved magnetron design, an improved substrate biasing configuration, and an improved process kit design.

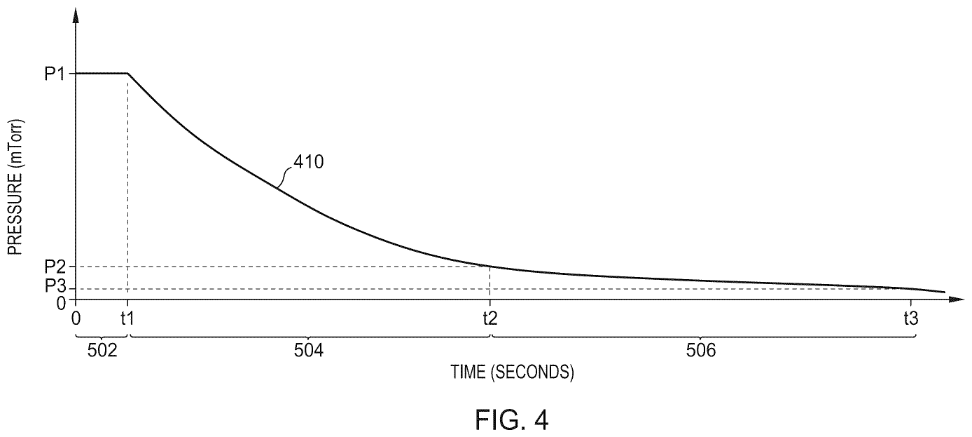

In one embodiment, the process chamber design disclosed herein is adapted to deposit a desired material using a PVD process that includes at least an ignition step, metal deposition transition step, and a low pressure metal deposition step. FIG. 4 includes a curve 410 that illustrates a chamber processing pressure as a function time during the PVD process, according to an embodiment. As described above, a deposition rate achieved on a substrate during the plasma striking process, which is performed at the moderate ignition pressures and moderate PVD target DC bias power levels to ignite and then sustain the plasma during the initial phases of the deposition process are often unavoidably too high to achieve a film thickness required to form a thin film layer within small structures formed on a substrate, such as 15 nanometer (nm) sized structures. Moreover, the characteristics of the deposited PVD film, which is formed by the generation of metal ions and neutrals sputtered from the target, are uncontrollable during these early stages of the deposition process and often account for an undesirable percentage of the final thickness of the deposited PVD film layer. Therefore, there is a need for a system, processing chamber, and method of controllably forming a thin PVD deposited layer within features formed within a substrate.

Embodiments of the disclosure provided herein include methods that are used reduce the deposition rate during one or more phases of a deposition process sequence in which the chamber pressure is too high to reliably generate the required low deposition rate levels, such as, for example, deposition rates on the order of less than 10 angstroms per second (Å/s) during a PVD deposition process. As will be discussed further below, the methods of controlling the deposition rate during a PVD deposition process includes controlling the amount of ion flux that reaches the surface of a substrate during a PVD deposition process.

### Processing System Example

FIG. 1 is a schematic top view of an exemplary processing system 100 (also referred to as a “processing platform”), according to certain embodiments. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the FOUPs 103 to at least one of the first load lock chamber 104 or the second load lock chamber 106. Proceeding counterclockwise around the transfer chamber 108 from the buffer portion 108A of the first load lock chamber 104, the processing system 100 includes a first degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, and a fourth processing chamber 138. In general, the processing chambers 132, 134, 136, 138 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138 are a PVD chamber that configured similar to the processing chamber 200 described below.

The buffer portion 108A and back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10⁻⁵ Torr (i.e., ~10⁻³ Pa). However, some high-vacuum systems may operate below near 10⁻⁷ Torr (i.e., ~10⁻⁵ Pa). In certain embodiments, the vacuum is created using a rough pump and/or a turbomolecular pump coupled to the transfer chamber 108 and to each of the one or more process chambers (e.g., process chambers 109-138). However, other types of vacuum pumps are also contemplated.

A system controller 126, such as a programmable computer, is coupled to the processing system 100 for controlling one or more of the components therein. For example, the system controller 126 may control the operation of the processing chamber 200, which is described further below. In operation, the system controller 126 enables data acquisition and feedback from the respective components to coordinate processing in the processing system 100. The system controller 126 includes a programmable central processing unit (CPU) 152, which is operable with a memory 154 (e.g., non-volatile memory) and support circuits 156. The support circuits 156 (e.g., cache, clock circuits, input/output subsystems, power supplies, etc., and combinations thereof) are conventionally coupled to the CPU 152 and coupled to the various components within the processing system 100.

In some embodiments, the CPU 152 is one of any form of general purpose computer processor used in an industrial setting, such as a programmable logic controller (PLC), for controlling various monitoring system component and sub-processors. The memory 154, coupled to the CPU 152, is non-transitory and is typically one or more of readily available memory such as random access memory (RAM), read only memory (ROM), floppy disk drive, hard disk, or any other form of digital storage, local or remote.

Herein, the memory 154 is in the form of a computer-readable storage media containing instructions (e.g., non-volatile memory), that when executed by the CPU 152, facilitates the operation of the processing system 100. The instructions in the memory 154 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Processing Chamber Example

FIG. 2 illustrates a processing chamber 200 having an upper process assembly 208, a process kit 250, flux optimizer 290, and a pedestal assembly 220, which are all configured to process a substrate 205 disposed in a processing region 210. The process kit 250 includes a one-piece grounded shield 260, a deposition ring 268, a cover ring 270, and an isolator ring assembly 280. In the version shown, the processing chamber 200 comprises a sputtering chamber, also called a PVD chamber, capable of depositing a single or multi-compositional material from a sputtering target 232 on the substrate 205. The processing chamber 200 may also be used to deposit aluminum (Al), copper (Cu), nickel (Ni), platinum (Pt), hafnium (Hf), silver (Ag), chrome (Cr), gold (Au), molybdenum (Mo), silicon (Si), ruthenium (Ru), tantalum (Ta), tantalum nitride (TaN), tantalum carbide (TaC), titanium nitride (TiN), tungsten (W), tungsten nitride (WN), lanthanum (La), alumina (AlOₓ), lanthanum oxides (LaOₓ), nickel platinum alloys (NiPt), and titanium (Ti), and or combination thereof. Such processing chambers are available from Applied Materials located in Santa Clara, Calif. It is contemplated that other processing chambers including those from other manufacturers may be adapted to benefit from one or more of the embodiments of the disclosure described herein.

The processing chamber 200 includes a chamber body 201 having sidewalls 204, a bottom wall 206, and an upper process assembly 208 that enclose a processing region 210 or plasma zone. The chamber body 201 is typically fabricated from welded plates of stainless steel or a unitary block of aluminum. In one embodiment, the sidewalls comprise aluminum and the bottom portion of the chamber includes one or more walls that are formed from a stainless steel plate. The sidewalls 204 generally contain a slit valve (not shown) to provide for entry and egress of a substrate 205 from the processing chamber 200. Components in the upper process assembly 208 of the processing chamber 200 in cooperation with the grounded shield 260, pedestal assembly 220 and cover ring 270 confine the plasma formed in the processing region 210 to the region above the substrate 205.

As shown in FIG. 2, a flux optimizer 290 can be optionally provided to control of the ion distribution and directionality of the deposited material in the chamber. The flux optimizer 290 is also referred to herein as a collimator in some embodiments. In one implementation, a control over ion flux directionality of sputtered material may be achieved by positioning the flux optimizer 290 between the sputtering target 232 and the pedestal assembly 220. FIG. 3 depicts a perspective view of a flux optimizer 290 in accordance with implementations of the present disclosure. The flux optimizer 290 includes a shield portion 310 coupled with a collimator portion 320. The collimator portion 320 includes a plurality of apertures 322 to direct and allow the passage of gas and/or material flux therethrough within the processing chamber 200. In some embodiments, the plurality of apertures 322 can include a vertical to lateral aspect ratio of between from about 1:1 to about 3:1. The collimator portion 320 may be mechanically and electrically coupled to the one-piece shield portion 310. In one implementation, the collimator portion 320 is integral to the one-piece shield portion 320, as shown in FIG. 3. In one implementation, the collimator portion 320 and the one-piece shield portion 310 are comprised of a material selected from aluminum, titanium, copper, and stainless steel. The collimator portion 320 functions as a filter to trap ions and neutral species that are emitted from the material from the sputtering target 232 at angles exceeding a selected angle, near normal relative to the substrate 205. The apertures 322 can include hexagonal shaped apertures that are designed to allow a different percentage of ions emitted from a center or a peripheral region of the material from the sputtering target 232 to pass through the collimator portion 320. As a result, both the number of ions and the angle of arrival of ions deposited onto peripheral regions and center regions of the substrate 205 are adjusted and controlled. In one implementation, the collimator portion 320 may be coupled to an AC or DC electrical power source 251. For example, a controllable DC or AC power source 251 may be coupled to the collimator portion 320 to provide an alternating pulsed positive or negative voltage to the collimator portion 320 relative to ground.

A pedestal assembly 220 is supported from the bottom wall 206 of the processing chamber 200. The pedestal assembly 220 supports a deposition ring 268 along with the substrate 205 during processing. The pedestal assembly 220 is coupled to the bottom wall 206 of the processing chamber 200 by a lift mechanism 222, which is configured to move the pedestal assembly 220 between an upper processing position and lower transfer position. Additionally, in the lower transfer position, lift pins 223 are moved through the pedestal assembly 220 to position the substrate a distance from the pedestal assembly 220 to facilitate the exchange of the substrate with a substrate transfer mechanism disposed exterior to the processing chamber 200, such as a single blade robot (not shown). A bellows 224 is typically disposed between the pedestal assembly 220 and the bottom wall 206 to isolate the processing region 210 from the interior of the pedestal assembly 220 and the exterior of the chamber.

The pedestal assembly 220 generally includes a support 226 sealingly coupled to a platform housing 228. The platform housing 228 is typically fabricated from a metallic material such as stainless steel or aluminum. A cooling plate (not shown) is generally disposed within the platform housing 228 to thermally regulate the support 226.

The support 226 may be comprised of aluminum or ceramic. The substrate support 226 has a substrate receiving surface 227 that receives and supports the substrate 205 during processing, the substrate receiving surface 227 being substantially parallel to a sputtering surface 233 of the sputtering target 232. The support 226 also has a peripheral edge 229 that terminates before an overhanging edge 205A of the substrate 205. The support 226 may be an electrostatic chuck, a ceramic body, a heater or a combination thereof. In one embodiment, the support 226 is an electrostatic chuck that includes a dielectric body having an electrode 226A, embedded therein. The dielectric body is typically fabricated from a high thermal conductivity dielectric material such as pyrolytic boron nitride, aluminum nitride, silicon nitride, alumina or an equivalent material. In one embodiment, the electrode 226A is configured so that when a DC voltage is applied to the electrode 226A, by an electrostatic chuck power supply 243, a substrate 205 disposed on the substrate receiving surface 227 will be electrostatically chucked thereto to improve the heat transfer between the substrate 205 and the support 226. In another embodiment, a bias source 241 is also coupled to the electrode 226A so that a voltage can be maintained on the substrate during processing to affect the plasma interaction with the surface of the substrate 205.

A program (or computer instructions) readable by the system controller 126 determines which tasks are performable on a substrate. Preferably, the program is software readable by the system controller 126 that includes code to perform tasks relating to monitoring, execution and control of the movement and various process recipe tasks and recipe steps being performed in the processing system 100 and processing chamber 200. For example, the system controller 126 can comprise program code that includes a substrate positioning instruction set to operate the pedestal assembly 220; a gas flow control instruction set to operate gas flow control valves to set a flow of sputtering gas to the processing chamber 200; a gas pressure control instruction set to operate a throttle valve or gate valve to maintain a pressure in the processing chamber 200; a temperature control instruction set to control a temperature control system (not shown) in the pedestal assembly 220 or sidewalls 204 to set temperatures of the substrate or sidewalls 204, respectively; and a process monitoring instruction set to monitor the process in the processing chamber 200.

The processing chamber 200 also contains a process kit 250 which comprises various components that can be easily removed from the processing chamber 200, for example, to clean sputtering deposits off the component surfaces, replace or repair eroded components, or to adapt the processing chamber 200 for other processes. In one embodiment, the process kit 250 comprises an isolator ring assembly 280, a grounded shield 260 and a deposition ring 268 for placement about a peripheral edge 229 of the support 226 that terminates before an overhanging edge of the substrate 205.

The upper process assembly 208 may include an RF source 281, a direct current (DC) source 282, an adaptor 202, a motor 293, and a lid assembly 230. The lid assembly 230 generally comprises a sputtering target 232, a magnetron system 289 and a lid enclosure 291. The upper process assembly 208 is supported by the sidewalls 204 when in a closed position, as shown in FIG. 2. A ceramic target isolator 236 is disposed between the isolator ring assembly 280, the sputtering target 232 and adaptor 202 of the lid assembly 230 to prevent vacuum leakage therebetween. The adaptor 202 is sealably coupled to the sidewalls 204, and is configured to help with the removal of the upper process assembly 208 and isolator ring assembly 280.

When in the processing position, the sputtering target 232 is disposed adjacent to the adaptor 202, and is exposed to the processing region 210 of the processing chamber 200. The sputtering target 232 contains material that is deposited on the substrate 205 during a PVD, or sputtering, process. The isolator ring assembly 280 is disposed between the sputtering target 232 and the shield 260 and chamber body 201 to electrically isolate the sputtering target 232 from the shield 260, flux optimizer 290, and chamber body 201.

During processing, the sputtering target 232 is biased relative to a grounded region of the processing chamber (e.g., chamber body 201 and adaptor 202) by a power source disposed in the RF source 281 and/or the direct current (DC) source 282. It is believed that by delivering RF energy and DC power to the sputtering target 232 during a low pressure PVD process, significant process advantages can be achieved over conventional moderate to high pressure DC plasma processing techniques when used in conjunction with sputtering materials such as titanium, copper, nickel, ruthenium, aluminum, tantalum, molybdenum, and tungsten to name just a few. In one embodiment, the RF source 281 comprises an RF power source 281A and an RF match 281B that are configured to efficiently deliver RF energy to the sputtering target 232. In one example, the RF power source 281A is capable of generating RF currents at a frequency of between about 13.56 MHz and about 228 MHz at powers between about 0 and about 5 kWatts. In one example, the DC power supply 282A in the DC source 282 is capable of delivering between about 0 and about 50 kWatts of DC power.

In some embodiments, the processing chamber 200 also includes one or more auxiliary electromagnet assemblies vertically aligned around the processing chamber, such as a first electromagnet assembly 261, a second electromagnet assembly 263, a third electromagnet assembly 265. In some embodiments, the first, second, and third electromagnet assemblies each include a separate current source so that each assembly can separately generate a magnetic field that is configured to confine and/or control the movement of electrons and ions generated in a plasma formed in the processing region 210 of the processing chamber.

In some embodiments, the first electromagnet assembly 261 comprises a first current source 261A configured to bias a first magnetic coil assembly 261B. The first magnetic coil assembly 261B is positioned near the sputtering target 232, configured to modulate the magnetron controlled plasma 213. The second electromagnet assembly 263 comprises a second current source 263A configured to bias a second magnetic coil assembly 263B. The second magnetic coil assembly 263B is positioned in the central part of the chamber, and configured to modulate a central portion of the plasma 211. The third electromagnet assembly 265 comprises a third current source 265A configured to bias a third magnetic coil assembly 265B. The third magnetic coil assembly 265B is positioned near the support 226, and configured to modulate the plasma near the surface of the substrate 205. In some configurations, the first, second, and third current sources 261A, 263A, and 265A are capable of generating a DC or RF current or voltage at a power between about 0 and about 10 kWatts.

In operation, the one or more electromagnet assemblies 261, 263, and 265 are vertically distributed and positioned outside the process kit 250 to generate magnetic field within the processing region 210 to help alter and/or shape the radial distribution of the plasma and control the trajectory of the ion flux generated from the sputtering target 232 formed with the processing region 210 during processing. In some embodiments, the one or more electromagnet assemblies comprise a single electromagnet, a pair of electromagnets, or a quadruple electromagnet array. The electromagnet array can include solenoidal wound coils wrapped generally circularly symmetrically about the central axis 294 of the processing chamber 200. The magnetic field generated by the electromagnet array is modulated by controlling the direction and magnitude of electric current flowing through each coil, or selectively powering a particular combination of coils, e.g., the outer/inner coils or the top/bottom coils.

The lid enclosure 291 generally comprises a conductive wall 285, a center feed 284 and shielding 286 (FIG. 2). In this configuration, the conductive wall 285, the center feed 284, the sputtering target 232 and a portion of the motor 293 enclose and form a back region 234. The back region 234 is a sealed region disposed on the back side of the sputtering target 232 and is generally filled with a flowing liquid during processing to remove the heat generated at the sputtering target 232 during processing. In one embodiment, the conductive wall 285 and center feed 284 are configured to support the motor 293 and magnetron system 289, so that the motor 293 can rotate the magnetron system 289 during processing. In one embodiment the motor 293 is electrically isolated from the RF or DC power delivered from the power supplies by use of a dielectric layer 293B, such as Delrin, G10, or Ardel.

To provide efficient sputtering, a magnetron system 289 is positioned over the back surface 235 of the sputtering target 232 in the upper process assembly 208 to create a magnetic field in the processing region 210 adjacent the sputtering surface 233 of the sputtering target 232, which creates a magnetron controlled plasma 213. The magnetic field by magnetron system 289 is created to trap electrons and ions to thereby increase the plasma density over one or more regions of the target 232, and to thereby also increase target utilization, control deposition uniformity and the sputtering rate. According to one embodiment of the disclosure, the magnetron system 289 includes a source magnetron assembly 221 that comprises an outer pole (not shown) and an inner pole (not shown). The magnetron system 289 is rotated about the central axis 294 of the processing chamber 200 by use of the motor 293. In some embodiments, a “closed loop” magnetron configuration is formed within the magnetron system 289 such that the outer pole (not shown) of the magnetron surrounds the inner pole (not shown) of the magnetron forming a gap between the poles that is a continuous loop. In the closed loop configuration, the magnetic fields that emerge and reenter through a surface of the sputtering target form a “closed loop” pattern can be used to confine electrons near the surface of the sputtering target in a closed pattern, which is often called a “racetrack” type pattern. A closed loop, as opposed to the open-loop, magnetron configuration is able to confine electrons and generate a high density plasma near the sputtering surface 233 of the sputtering target 232 to increase the sputtering yield. In some other embodiments, an “open loop” magnetron configuration is formed within the magnetron system 289 such that the outer pole of the magnetron surrounds the inner pole of the magnetron forming a gap between the poles that is a continuous loop. In an open loop magnetron configuration, the electrons trapped between the inner and outer poles will migrate, leak out and escape from the B-fields created at open ends of the magnetron, thus only holding the electrons for a short period of time during the sputtering process due to the reduced confinement of the electrons. It has been found that the use of an open loop magnetron configuration, can provide significant step coverage improvements and provide an improved material composition uniformity across the substrate surface, when used in conjunction with the RF and DC sputtering of multi-compositional targets described herein.

In some embodiments of the processing chamber 200, the bias source 241 is coupled between an electrode and RF ground to adjust the bias voltage on the substrate 205 during processing to control the degree of bombardment on the substrate surface. In some embodiments, the electrode is disposed adjacent to the substrate receiving surface 227 of a support 226, and comprises the electrode 226A. In a PVD reactor, tuning of the bombardment of the substrate surface by the control of the impedance of the electrode to ground, will affect step coverage, overhang geometry and deposited film's properties, such as grain size, film stress, crystal orientation, film density, roughness, feature bottom coverage, feature step coverage and in some cases can effect film composition. Therefore, the bias source 241 can thus be used to alter the deposition rate, the etching rate and even the composition of a multi-compositional film at the substrate surface. In one embodiment, the bias source 241 is employed to enable deposition or etching of a deposited film, by the appropriate adjustment of impedance of the electrode/substrate to ground. In one embodiment of the bias source 241, the bias source 241 that has a variable capacitor tuning circuit with a feedback circuit to control the properties of a deposited metal or non-metal layer on a substrate.

In general, during a PVD deposition process, a gas is supplied to the processing region 210 from a gas source 242 via conduits 244. A plasma is formed between the substrate 205 and the sputtering target 232 using the gas. Ions within the plasma are accelerated toward the sputtering target 232 and cause material to become dislodged from the sputtering target 232. The dislodged target material, which includes ions and neutral atoms sputtered from the target surface are deposited on the substrate. The gas source 242 may comprise and deliver an inert gas such as argon, krypton, helium or xenon, which is capable of energetically impinging upon and sputtering material from the sputtering target 232 and/or surface of the substrate 205 based on a bias applied by the bias source 241. The gas source 242 may also include a reactive gas, such as one or more of an oxygen-containing gas or a nitrogen-containing gas, which is capable of reacting with the sputtering material to form a layer on a substrate.

Spent process gas and byproducts are exhausted from the processing chamber 200 through exhaust ports 246 that receive spent process gas and direct the spent process gas to an exhaust conduit 248 having an adjustable position gate valve 247 to control the pressure in the processing region 210 in the processing chamber 200. The exhaust conduit 248 is connected to one or more exhaust pump 249, such as a cryopump. The pressure of the sputtering gas in the processing chamber 200 during processing is set to sub-atmospheric levels, such as a vacuum environment, for example, a pressure of about 0.5 mTorr to about 400 mTorr, which is set to enable a plasma to be sustained during the deposition process.

### Processing Method Examples

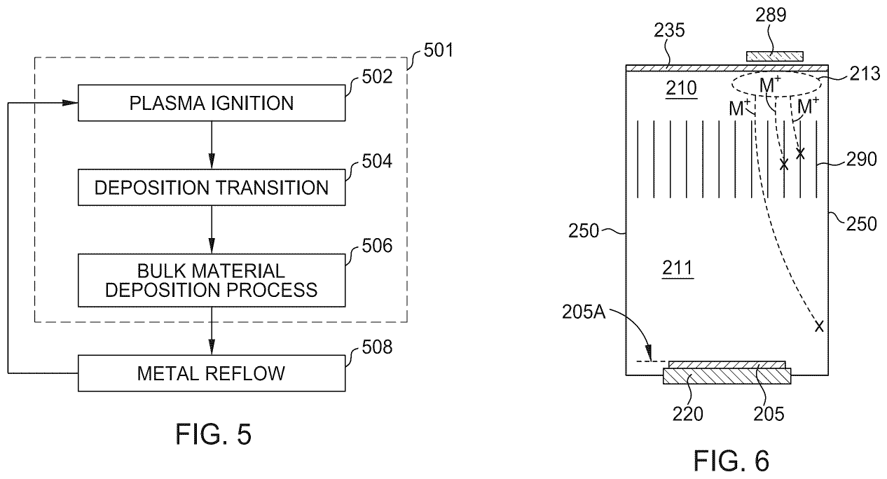

FIG. 5 depicts a process flow diagram of a method 500 for depositing a layer on a surface of a substrate, according to one or more embodiments of the present disclosure. The method 500 includes PVD deposition process 501 and an optional reflow process 508. Referring to FIGS. 2 and 4-5, in some embodiments, a PVD process 501 includes a plasma ignition step 502, deposition transition step 504, and a low pressure deposition step 506.

At operation 502, a process gas is flowed into the processing region 210 from the gas source 242 to increase the pressure inside of the deposition chamber 200 to a first pressure (i.e., pressure P1 in FIG. 4). In some embodiments, the processing pressure P1 during operation 502 is preferably set within a range that is greater than 20 mTorr, such as between about 20 mTorr and about 100 mTorr, while a DC power is applied to the target, to reliably generate a sustainable plasma 213 within the processing region 210. In one example, a DC power of greater than 0.5 kilowatt (kW) is applied during operation 502, such as between about 1 kW and about 5 kW is applied to the target 232 to generate a plasma 213 within the deposition chamber 200. In some embodiments, the process gas provided during the method 500 may include argon (Ar). However, other suitable process gases may be used, such as, for example, helium (He), neon (Ne), krypton (Kr), xenon (Xe), nitrogen (N₂), or the like.

Once a plasma 213 has been formed within the processing region 210 it has been found advantageous to drop the pressure within the processing region 210 to a low pressure level, such as less than 5 mTorr, or less than 1 mTorr, or even less than 0.1 mTorr, or even less than 0.01 mTorr, to deposit the bulk portion of the thin film layer using a low pressure deposition process, such as a process that utilizes a self-ionized-plasma (SIP) mode of deposition during the bulk deposition process performed during operation 506. Low pressure PVD deposition processes, such as SIP sputtering mode of deposition processes, are particularly useful for forming a high ionization fraction of the sputtered target atoms, which can then be used to enable the control of the flux and deposition rate of the sputtered metal atoms. To achieve an ionization fraction percentage and desired deposition rate, the process gas (e.g., Ar) working pressure needs to be reduced from the pressure P1 used during plasma ignition step to a desired low pressure level (e.g., pressure P2 in FIG. 4). The reduced pressure during the subsequent phases of the deposition process also reduces the likelihood of the sputtered metal ions colliding with argon atoms, which would both reduce the ion density and randomize the metal ion sputtering pattern.

At operation 504, the pressure is transitioned from the process pressure P1 (FIG. 4) utilized during operation 502 to a desired processing pressure P2 by removing a significant portion of the process gas (e.g., Ar) by use of the exhaust pump 249. The length of the transition period between the end of operation 502 and the start of operation 506 will depend on the pumping speed of the exhaust pump 249 and the ability of the gas source 242 to reduce the flow rate of the process gas to a desired flow rate to achieve the desired processing pressure P2 which signals the start to the bulk deposition process performed during operation 506.

In an effort to assure that the plasma 213 generated during operation 502 is stable and will not become extinguished, the bias power applied to the target 232 is adjusted to a desired level, such as a higher power level due to the desired reduction in the amount of the process gas (e.g., chamber pressure) within processing region 210 during operation 504. In one example, a DC power of greater than 5 kilowatt (kW) is applied to the target 232 during operation 504, such as greater than 10 kW, or greater than 15 kW, or even greater than 20 kW, such as between about 10 kW and about 25 kW is applied to the target 232 to generate a plasma 213 within the deposition chamber 200.

As noted above, conventional deposition processes performed within the pressure range traversed during a transition from the end of operation 502 and the start of operation 506 are generally uncontrollable, and will generate a deposition rate that is often too large for a thin metal layer deposition process. In an effort to avoid these issues, one or more of the methods disclosed herein are used to control various aspects of the deposition process, such as the deposition rate during operation 504. In some embodiments, the one or more controlled aspects of the deposition process include controlling the amount of ion flux that reaches the surface of a substrate during operation 501.

In some embodiments, during operation 504, a significant portion of the ionized atoms generated from the sputtering of the PVD target 232 are diverted from their trajectory formed during the process of sputtering material from the surface of the target 232 to a trajectory that will prevent a significant portion of the ions from reaching the surface of the substrate. In one example, as shown in FIG. 6, the trajectory of the ionized sputtered atoms (M⁺) are diverted to a side wall of the chamber (e.g., process kit 250) and/or side wall of the flux optimizer 290 by use of electromagnets within the PVD chamber versus to the surface of the substrate 205. The process of diverting the ionized sputtered atoms (M⁺) away from the surface of the substrate during operation 504 is performed by use of an algorithm within the controller 126 that is configured to adjust one or more of the process parameters (e.g., B-field generated by one or more electromagnets, chamber pressure, gas flow rate, etc.) to control the deposition rate and amount of deposited material that is provided to the surface of the substrate during operation 504.

In some embodiments, it is desirable to reduce the ion flux reaching the substrate during operation 504 to reduce off angle ions flux, since: (1) these off angle ions (e.g., non-normal angled ions) can be hard to control by use of an AC bias applied to the substrate, and (2) the off-angle ions often don't have enough ion energy to fill the bottom of the structure. Also, since it is common for the ion distribution from a rotating magnetron PVD configuration to include a very non-uniform deposition profile (e.g., ion flux to the center of the substrate is significantly lower than edge of the substrate) it is desirable to alter the trajectory of the ion flux away from the edge of the substrate, and thus mitigating this non-uniformity problem.

In one configuration, by applying and/or adjusting a bias applied to the first electromagnet assembly 261, the second electromagnet assembly 263, and/or the third electromagnet assembly 265 the trajectory of the sputtered ions towards the substrate can be controlled, and thus the deposition rate can be adjusted. In some embodiments, the first, second, and third electromagnet assemblies each include a separate current source (e.g., items 261A, 263A, and 265A) so that each assembly can separately generate a magnetic field (i.e., B-field) that is configured to control the movement of the ions generated in a plasma formed in the processing region 210 of the processing chamber.

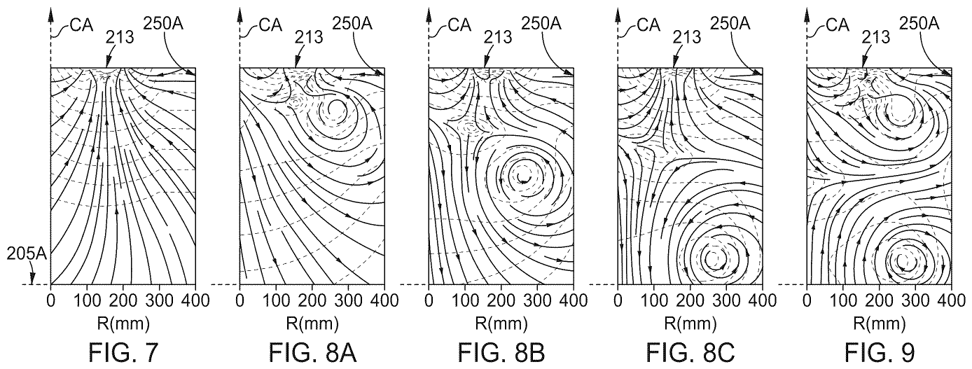

FIG. 7 illustrates a plurality of magnetic field lines generated within the processing region 210 of the deposition chamber 200 by a magnetron 289 that is positioned over a right hand side portion of a target 232, and is outlined in FIG. 2. In some embodiments, the field line pattern illustrated in FIG. 7 can be formed within the deposition chamber 200 while a substrate bias is applied by the bias source 241, which is coupled to the electrode 226A.

Similar to FIG. 7, FIGS. 8A-8C and 9 each include an illustration of magnetic field lines generated within the processing region 210 by the magnetron 289, and one or more of the electromagnet assemblies 261, 263, 265, wherein the left edge of FIGS. 7-9 are bounded by the central axis CA of the deposition chamber 200 and the right edge of FIGS. 7-9 are bounded by a portion of a process kit 250 (e.g., shield) component.

As illustrated in FIG. 7, in the absence of a generated B-field by the one or more of the electromagnet assemblies 261, 263, 265 the field lines will generally extend between the magnetron's position over a region of the target 232 to the process kit 250 and the substrate support 220, as shown by the primarily vertically oriented field lines shown in FIG. 7. In this case, the trajectory of the ionized sputtered atoms will be primarily in a vertical direction and towards the surface of the substrate support.

FIG. 8A illustrates a plurality of magnetic field lines generated within the processing region 210 by a magnetron 289 and a bias applied to the first electromagnet assembly 261. As illustrated in FIG. 8A, due to the position of the first electromagnet assembly 261 in the upper portion of the processing region 210 and above the flux optimizer 290, the generated B-field by the electromagnet assembly 261 can be used to alter the trajectory the ionized sputtered atoms within a region formed between the target surface and the flux optimizer 290 to a trajectory that is away from the surface of the substrate and towards the walls of the flux optimizer 290 and process kit 250. By controlling the strength of the B-field the amount of ion flux that will arrive at the surface of the substrate can be adjusted and the deposition rate seen on the surface of the substrate can be reduced and controlled. It has been found that the application and adjustment of a bias to a first electromagnetic assembly 261, which is positioned near the surface of the target 232 and/or in a region formed between the flux optimizer 290 and target 232 can provide a significant ion flux controlling adjustment during one or more phases of the deposition process 501.

FIG. 8B illustrates a plurality of magnetic field lines generated within the processing region 210 by a magnetron 289 and a bias applied to the second electromagnet assembly 263. As illustrated in FIG. 8B, due to the position of the second electromagnet assembly 263 in the central portion of the processing region 210, the generated B-field by the second electromagnet assembly 263 can be used to alter the trajectory the ionized sputtered atoms within a region formed between the flux optimizer 290 and the surface of the substrate support 220, and away from the surface of the substrate and towards the walls of the process kit 250. By controlling the strength of the B-field generated by the second electromagnet assembly 263, the amount of ion flux that will arrive at the surface of the substrate can be adjusted and the deposition rate seen on the surface of the substrate can be reduced and controlled.

FIG. 8C illustrates a plurality of magnetic field lines generated within the processing region 210 by a magnetron 289 and a bias applied to the third electromagnet assembly 265. As illustrated in FIG. 8C, due to the position of the third electromagnet assembly 265 in the lower portion of the processing region 210, the generated B-field by the third electromagnet assembly 265 can also be used to alter the trajectory the ionized sputtered atoms within a region formed between the flux optimizer 290 and the surface of the substrate support 220, and away from the surface of the substrate and towards the walls of the process kit 250. By controlling the strength of the B-field generated by the third electromagnet assembly 265, the amount of ion flux that will arrive at the surface of the substrate can be adjusted and the deposition rate seen on the surface of the substrate can be reduced and controlled.

FIG. 9 illustrates a plurality of magnetic field lines generated within the processing region 210 by a magnetron 289 and a bias applied to the first electromagnet assembly 261 and the third electromagnet assembly 265. As illustrated in FIG. 9, due to the position of the combination of the biases applied by the first electromagnet assembly 261 and the third electromagnet assembly 265, the generated combined B-field can be used to alter the trajectory the ionized sputtered atoms within the processing region 210 and away from the surface of the substrate and towards the walls of the process kit 250. By controlling the combination of the applied B-fields generated by two or more of electromagnet assembly, the amount of ion flux that will arrive at the surface of the substrate can be further adjusted and tailored to provide a desired control of the deposition rate seen on the surface of the substrate.

In at least one embodiment of the method 500, the flux optimizer 290 can be grounded or biased relative to ground during one or more phases of the deposition process 501 to provide an independent or an additional process controlling variable to control of the trajectory of the sputtered ion flux within the processing region 210 of the deposition chamber 200. A bias applied to the flux optimizer 290 can be created by applying a voltage via the AC or DC electrical power source 251. In one or more embodiments, a positive or a negative voltage relative to ground of about 10 V to about 200 V is applied to the flux optimizer 290. In one example, a negative DC voltage bias is applied to the flux optimizer to cause ions within the formed plasma 213 to be deposited on a surface of the apertures and/or shield portion of the flux optimizer 290. As discussed above, in some embodiments, an RF bias can be applied to the flux optimizer 290.

At operation 506, once the pressure within the processing region 210 reaches a desired low pressure level, such as pressure P2, the bias power applied to the target 232 is adjusted to allow the deposition process to continue at a desired rate at the low pressure level. Operation 506 is generally performed at a chosen target bias power level for a length of time necessary to sputter deposit the chosen thickness of material. In one example, a DC power of greater than 10 kilowatt (kW) is applied to the target 232 during operation 506, such as greater than 15 kW, or greater than 20 kW, or even greater than 25 kW, such as between about 25 kW and about 50 kW, or even between about 30 kW and about 40 kW, is applied to the target 232 to sustain the plasma 213 within the deposition chamber 200, while the pressure within the processing region 210 a pressure less than 5 mTorr.

In some embodiments of method 500, the bias applied to the first electromagnet assembly 261, the second electromagnet assembly 263, and/or the third electromagnet assembly 265 during operation 504 is stopped or significantly reduced to allow the trajectory of the ion flux to be allowed to be directed to the substrate surface by use of a bias applied to the substrate support or an adjustment of the magnetic field generated by the electromagnet assemblies to guide the ion flux towards the substrate surface. In other embodiments, the bias applied to the first electromagnet assembly 261, the second electromagnet assembly 263, and/or the third electromagnet assembly 265 is provided during operation 506 at a level that causes at least a portion of the generated sputtered ions to be directed away from the substrate surface, or in other words reduces the flux of the ionized sputtered atoms reaching the surface of a substrate, to control the amount of ion flux that is deposited on the process kit 250 components and surface of the substrate 232. In some embodiments, applying a first bias to the first electromagnet assembly 261, the second electromagnet assembly 263, and/or the third electromagnet assembly 265 reduces the flux of the ionized sputtered atoms reaching the surface of a substrate during the deposition process by at least 10%, such as by at least 20%, or by at least 30%, or by at least 40%, or by at least 50%, or by at least 75%, or by at least 80%, or by at least 90%, or by at least 95%, or even by at least 99%. In one example, the reduction in the flux of the ionized sputtered atoms reaching the surface of a substrate is measured by comparing the amount deposition (e.g., film thickness) received on two successive substrates that are processed using the same processing condition except for the application of a first bias applied to the first electromagnet assembly 261, the second electromagnet assembly 263, and/or the third electromagnet assembly 265 during one of the two successive substrate deposition processes.

At operation 508, an optional reflow process is performed on the substrate. After deposition of the deposited layer (e.g., operation 501), the temperature of the substrate is raised to a reflow temperature during operation 508. It is believed that the reflow process advantageously improves filling of the one or more features during the reflow process and reduces voids within the one or more features formed on the surface of the substrate. In operation 508, the substrate is heated to a reflow temperature in a vacuum environment to cause the reflow of the layer deposited during operation 501, such as a cobalt (Co), copper (Cu), or aluminum (Al), and alloys thereof, containing layer. The reflow temperature can include a high temperature which may range from approximately 200 degrees Celsius to approximately 400 degrees Celsius. The deposition process 501 and heating of the deposited layer during operation 508 may be a cyclic process that is performed more than once.

Although the invention is particularly useful at the present time for copper inter-level metallization and barrier and liner deposition, the different aspects of the invention may be applied in sputtering other materials and/or other purposes.

### Neutral Flux Analysis

In some embodiments, it is desirable to determine an amount of neutral atom flux (e.g., neutral atom deposition rate) provided to the surface of the substrate during a deposition process so that one or more deposition process variables can be adjusted to adjust the amount of neutrals and ions that are generated. One or more of the deposition process variables can include altering the sputtered atom ionization percentage in the plasma and plasma density during one or more phases of the deposition process 501. The amount of neutral flux can be determined by use of Equation 1 below.

Total TDR=IDR (ion Flux)+NDR (neutral Flux), (eq. 1)

where the total deposition rate (TDR) is the deposition rate of a material layer formed on the surface of a substrate due to the sum of ion flux (e.g., IDR (ion flux)) and neutral flux (e.g., NDR (neutral flux)).

The process of determining the neutral atom flux will include depositing a first material layer on a first substrate for a first period of time, at a desired process pressure and DC target bias. Then depositing a second material layer on a second substrate for the same length of time, at the same desired process pressure and DC target bias, while also applying a bias to the first electromagnet assembly 261, the second electromagnet assembly 263, and/or the third electromagnet assembly 265 during operations 504 and/or 506 to a level such that the ion flux delivered to the substrate is negligible, and thus allowing the predominant amount of the second deposited layer formed on the surface of the second substrate to be due to the neutral atom flux. Then by comparing the differences in thickness the contribution of the neutral flux and deposition rate can be determined by subtracting the second thickness from the first thickness and dividing by the first period of time. If the neutral flux contribution to the deposition rate is too high, the target bias, a bias applied to the flux optimizer 290, or chamber pressure during processing, for example, can be adjusted to increase the ionization fraction during one or more phases of the deposition process. Therefore, in some embodiments, the information relating to an amount of neutral atom flux achieved at a desired set of deposition processing conditions can be subsequently used to alter one or more of the process variables, which will include target bias, processing pressure, bias applied to the flux optimizer 290, or other useful process variable can then be used in future substrate deposition processes.

While the foregoing is directed to embodiments of the present disclosure, other and further embodiments of the disclosure may be devised without departing from the basic scope thereof, and the scope thereof is determined by the claims that follow.

What is claimed is:

1. A method of depositing a material layer on a surface of a substrate, comprising:
generating a plasma within a processing region of a processing chamber, wherein
the processing region is disposed between a target and a substrate support,
the plasma is generated by biasing the target at a first power level while the processing region is maintained at a first processing pressure, and
the plasma comprises ionized atoms sputtered from the target;
applying a first bias to a first electromagnet that is positioned to generate a magnetic field within the processing region, wherein
applying the first bias to the first electromagnet causes a flux of the ionized atoms sputtered from the target to be directed away from a surface of the substrate support, and
the first bias is applied to the first electromagnet while the processing region is at a pressure between the first processing pressure and a second processing pressure and the target is biased at a second power level; and
adjusting the bias applied to the target to a third power level while a pressure within the processing region is less than or equal to the second processing pressure.

2. The method of claim 1, wherein applying the first bias to the first electromagnet reduces the flux of the ionized atoms reaching the surface of the substrate by at least 90%.

3. The method of claim 2, wherein a side wall of the processing chamber comprises a grounded shield that surrounds at least a portion of the processing region.

4. The method of claim 1, further comprises applying a second bias to a second electromagnet that is positioned to generate a magnetic field within the processing region, wherein applying the first bias to the first electromagnet and the second bias to the second electromagnet reduces the flux of the ionized atoms reaching the surface of the substrate by at least 90%.

5. The method of claim 1, wherein the processing chamber further comprises a flux optimizer that is disposed between the target and the substrate support, and the flux optimizer comprises a plurality of apertures that extend in a direction that extends between the target and the substrate support.

6. The method of claim 5, wherein the processing chamber further comprises a power source that is configured to bias the flux optimizer relative to a ground.

7. The method of claim 5, wherein the flux optimizer is grounded while biasing the electromagnet.

8. The method of claim 1, wherein the second processing pressure is less than the first processing pressure.

9. The method of claim 8, wherein the second processing pressure is less than 5 mTorr.

10. The method of claim 1, wherein the third power level is greater than the second power level.

11. The method of claim 1, wherein the adjusting the bias applied to the target to the third power level further comprises:
adjusting a bias applied to the first electromagnet to a second bias level, wherein the second bias level is different from a first bias level applied to the first electromagnet during the application of the first bias.

12. The method of claim 1, further comprises applying a second bias to a second electromagnet that is positioned to generate a magnetic field within the processing region, wherein
applying the second bias to the second electromagnet causes a flux of the ionized atoms sputtered from the target to be directed away from the surface of the substrate support, and
the second bias is applied to the second electromagnet while the processing region is at the pressure between the first processing pressure and the second processing pressure and the target is biased at the second power level.

13. A processing chamber, comprising:
a substrate support;
one or more walls, wherein a target, the substrate support and the one or more walls define a processing region;
a first electromagnet that is positioned to generate a magnetic field within the processing region; and
a memory that includes instructions stored therein, which when executed by a processor are configured to perform a method comprising:
generating a plasma within the processing region by biasing the target at a first power level while the processing region is maintained at a first processing pressure, wherein the plasma comprises ionized atoms sputtered from the target;
applying a first bias to the first electromagnet, wherein applying the first bias causes a flux of the ionized atoms sputtered from the target to be directed away from the substrate support, and the first bias is applied to the first electromagnet while the processing region is at a pressure between the first processing pressure and a second processing pressure and the target is biased at a second power level; and
adjusting the bias applied to the target to a third power level while a pressure within the processing region is less than or equal to the second processing pressure.

14. The processing chamber of claim 13, wherein the one or more walls comprise a grounded shield that surrounds at least a portion of the processing region.

15. The processing chamber of claim 13, further comprising a flux optimizer that is disposed between the target and the substrate support, and the flux optimizer comprises a plurality of apertures that extend in a direction that extends between the target and the substrate support.

16. The processing chamber of claim 15, wherein the processing chamber further comprises a power source that is configured to bias the flux optimizer relative to a ground.

17. The processing chamber of claim 15, wherein the flux optimizer is grounded while applying the first bias to the first electromagnet.

18. The processing chamber of claim 15, wherein the second processing pressure is less than the first processing pressure.

19. The processing chamber of claim 13, further comprises:
a second electromagnet that is positioned to generate a magnetic field within the processing region, wherein the method further comprises:
applying a second bias to the second electromagnet, wherein applying the second bias to the second electromagnet causes a flux of the ionized atoms sputtered from the target to be directed away from a surface of the substrate support, and
the second bias is applied to the second electromagnet while the processing region is at the pressure between the first processing pressure and the second processing pressure and the target is biased at the second power level.

20. The processing chamber of claim 13, wherein applying the first bias to the first electromagnet reduces the flux of the ionized atoms reaching a surface of a substrate by at least 10%.
